(19) United States
(12) Patent Application Publication
(10) Pub. No.: US 2025/0015120 A1
(43) Pub. Date: Jan. 9, 2025

(54) DETECTION DEVICE

(71) Applicant: Japan Display Inc., Tokyo (JP)

(72) Inventor: Gen KOIDE, Tokyo (JP)

(21) Appl. No.: 18/890,047

(22) Filed: Sep. 19, 2024

Related U.S. Application Data
(63) Continuation of application No. PCT/JP2023/010558, filed on Mar. 17, 2023.

(30) Foreign Application Priority Data
Mar. 29, 2022 (JP) 2022-053008

(51) Int. Cl. H01L 27/146

(52) U.S. Cl. CPC H01L 27/14643; H01L 27/14623

(57) ABSTRACT

According to an aspect, a detection device includes: a substrate; a photodiode that is provided on the substrate and in which a lower electrode, a lower buffer layer, an active layer, an upper buffer layer, and an upper electrode are stacked on the substrate in the order as listed; a signal line that is provided between the substrate and the photodiode in a direction orthogonal to the substrate and is electrically coupled to the lower electrode of the photodiode; a detection circuit electrically coupled to the photodiode via the signal line; and a shield layer that is provided between the signal line and the lower buffer layer in the direction orthogonal to the substrate and is configured to be supplied with a reference voltage.

### CROSS-REFERENCE TO RELATED APPLICATION

This application claims the benefit of priority from Japanese Patent Application No. 2022-053008 filed on Mar. 29, 2022 and International Patent Application No. PCT/JP2023/010558 filed on Mar. 17, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (refer to, for example, Japanese Patent Application Laid-open Publication No. 2009-32005). Such optical sensors each include a plurality of photodiodes each including an organic semiconductor material as an active layer. As described in International Patent Application Publication No. WO/2020/188959, each of the photodiodes is disposed between a lower electrode and an upper electrode; and, for example, the lower electrode, an electron transport layer, the active layer, a hole transport layer, and the upper electrode are stacked in this order. The electron transport layer and the hole transport layer are also called buffer layers.

If parasitic diodes and parasitic capacitance are generated between a plurality of signal lines and the upper electrode of the photodiodes, coupling occurs between the parasitic diodes and the signal lines via the parasitic capacitance, and the potential of the signal lines may be varied by leakage from the parasitic diodes. As a result, errors may occur in detection signals output from the photodiodes to a detection circuit.

For the foregoing reasons, there is a need for a detection device capable of improving accuracy of detection.

### SUMMARY

According to an aspect, a detection device includes: a substrate; a photodiode that is provided on the substrate and in which a lower electrode, a lower buffer layer, an active layer, an upper buffer layer, and an upper electrode are stacked on the substrate in the order as listed; a signal line that is provided between the substrate and the photodiode in a direction orthogonal to the substrate and is electrically coupled to the lower electrode of the photodiode; a detection circuit electrically coupled to the photodiode via the signal line; and a shield layer that is provided between the signal line and the lower buffer layer in the direction orthogonal to the substrate and is configured to be supplied with a reference voltage.

### BRIEF DESCRIPTION OF THE DRAWINGS

FIG. 1 is a plan view illustrating a detection device according to a first embodiment;

FIG. 2 is a sectional view along II-II′ of FIG. 1;

FIG. 3 is a sectional view illustrating a detection device according to a first modification of the first embodiment;

FIG. 4 is a plan view illustrating a detection device according to a second embodiment;

FIG. 5 is a sectional view along V-V′ of FIG. 4; and

FIG. 6 is a sectional view illustrating a detection device according to a second modification of the second embodiment.

### DETAILED DESCRIPTION

The following describes modes (embodiments) for carrying out the present invention in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

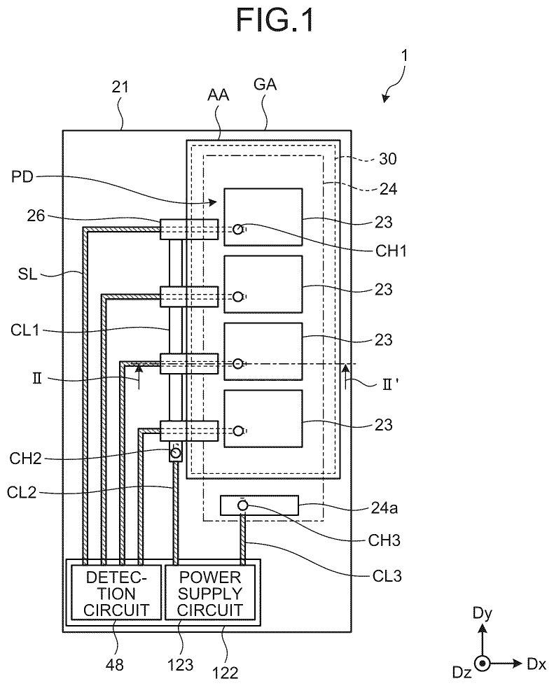

FIG. 1 is a plan view illustrating a detection device according to a first embodiment. As illustrated in FIG. 1, a detection device 1 includes a substrate 21, a plurality of photodiodes PD, a plurality of signal lines SL, a plurality of shield layers 26, power supply wiring lines CL1, CL2, and CL3, and a control circuit 122.

The substrate 21 has a detection area AA and a peripheral area GA. The detection area AA is an area provided with the photodiodes PD. The peripheral area GA is an area between the outer perimeter of the detection area AA and the ends of the substrate 21 and is an area not provided with the photodiodes PD. The signal lines SL and the control circuit 122 are provided in the peripheral area GA of the substrate 21.

In the following description, a first direction Dx is one direction in a plane parallel to the substrate 21. A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy. The third direction Dz is a direction normal to the substrate 21. The term “plan view” refers to a positional relation when viewed in a direction orthogonal to the substrate 21.

The detection device 1 includes the photodiodes PD as optical sensor elements. Each of the photodiodes PD outputs an electrical signal corresponding to light emitted thereto. More specifically, the photodiode PD is an organic photodiode (OPD) including an organic semiconductor. The photodiodes PD are arranged in the second direction Dy in the detection area AA.

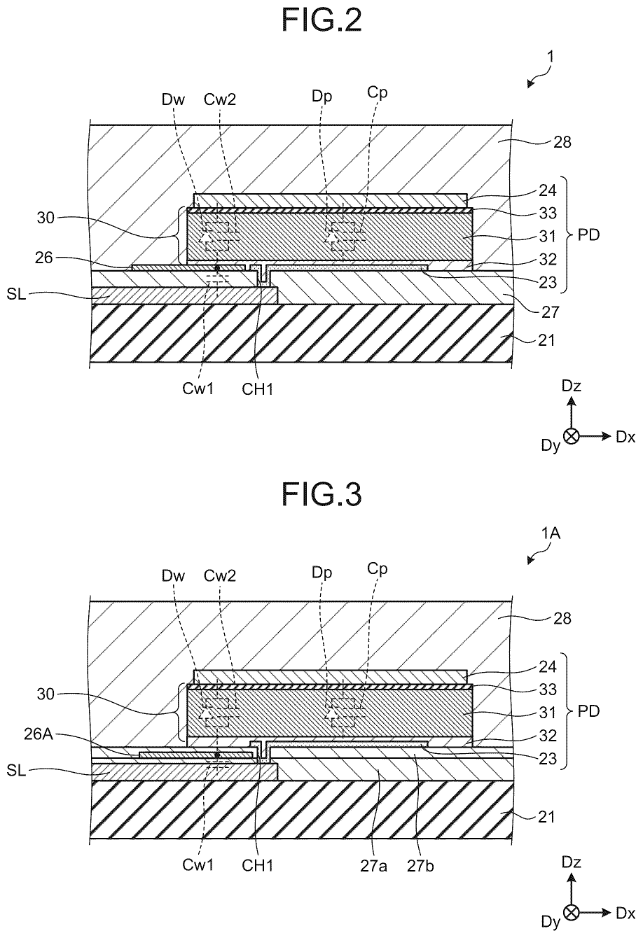

The photodiodes PD each include an organic semiconductor layer 30 (a lower buffer layer 32, an active layer 31, and an upper buffer layer 33 (refer to FIG. 2)), lower electrodes 23 disposed below the organic semiconductor layer 30, and an upper electrode 24 disposed on the organic semiconductor layer 30. A plurality of the lower electrodes 23 are provided, one for each of the photodiodes PD, and are arranged in the second direction Dy in the detection area AA. The lower electrodes 23 are arranged apart from one another in the second direction Dy. The organic semiconductor layer 30 and the upper electrode 24 are provided across the photodiodes PD and are provided continuously in the detection area AA. To facilitate viewing of the drawing, FIG. 1 illustrates the organic semiconductor layer 30 and the upper electrode 24 provided on the upper side of the lower electrode 23 with a dashed line and a long dashed double-short dashed line, respectively. The multilayer configuration of the photodiodes PD, the lower electrodes 23, and the upper electrode 24 will be described later with reference to FIG. 2.

The signal lines SL are each electrically coupled to a corresponding one of the lower electrodes 23 of the photodiodes PD. Specifically, in the example illustrated in FIG. 1, the signal lines SL are each coupled to a corresponding one of the lower electrodes 23 through a contact hole CH1 formed in an insulating film 27 (illustrated in FIG. 2).

Each of the signal lines SL extends in the first direction Dx from a coupling point (contact hole CH1) with the lower electrode 23, bends to the second direction Dy, and extends in the second direction Dy along the arrangement direction of the photodiodes PD. Portions of the signal lines SL extending in the second direction Dy are arranged in the first direction Dx. The signal lines SL are coupled to a detection circuit 48 included in the control circuit 122. In other words, the detection circuit 48 is electrically coupled to the lower electrodes 23 of the photodiodes PD through the signal lines SL.

Each of the signal lines SL and each of the shield layers 26 are provided for a corresponding one of the photodiodes PD. The shield layers 26 are arranged so as to overlap the respective signal lines SL in plan view. In more detail, the shield layers 26 each overlap a portion of a corresponding one of the signal lines SL extending in the first direction Dx and extend in the first direction Dx along the signal lines SL. The shield layers 26 each extend across the detection area AA and peripheral area GA. The shield layers 26 are arranged in the second direction Dy so as to overlap the respective signal lines SL.

The width in the first direction Dx of the organic semiconductor layer 30 is larger than the width in the first direction Dx of the lower electrode 23. The organic semiconductor layer 30 and the upper electrode 24 of the photodiodes PD are provided extending across the lower electrodes 23 and are also provided so as to overlap portions of the signal lines SL. One side of the outer edge of the organic semiconductor layer 30 intersects the portions of the signal lines SL extending in the first direction Dx. The shield layers 26 are provided at intersections between the one side of the outer edge of the organic semiconductor layer 30 and the signal lines SL. In other words, the shield layers 26 include portions overlapping the organic semiconductor layer 30 and portions not overlapping the organic semiconductor layer 30.

The shield layers 26 are coupled to a power supply circuit 123 included in the control circuit 122 via the power supply wiring lines CL1 and CL2 extending in the second direction Dy. More specifically, the power supply wiring line CL1 is provided in the same layer as the shield layers 26 and is provided so as to intersect the shield layers 26. As a result, the shield layers 26 are collectively coupled to the common power supply wiring line CL1. The power supply wiring line CL2 is provided in the same layer as the signal lines SL and is electrically coupled to the power supply wiring line CL1 through a contact hole CH2. The power supply wiring line CL2 is electrically coupled to the power supply circuit 123.

With such a configuration, the power supply circuit 123 supplies a reference voltage VCOM to the shield layers 26 via the power supply wiring lines CL1 and CL2. The reference voltage VCOM is a voltage signal having a fixed predetermined potential. The reference voltage VCOM is, for example, a voltage signal having an equal potential to a sensor reference voltage COM supplied to the lower electrodes 23. The power supply wiring line CL1 is provided adjacent to the organic semiconductor layer 30 in the first direction Dx. However, the coupling between the shield layers 26 and the power supply circuit 123 may have any configuration, and the arrangement, the number, and the like of the power supply wiring lines CL1 and CL2 can be changed as appropriate.

The upper electrode 24 is provided so as to extend in the second direction Dy across the detection area AA and the peripheral area GA. That is, the upper electrode 24 is provided so as to extend from an area overlapping the organic semiconductor layer 30 to an area not overlapping the organic semiconductor layer 30, and is electrically coupled to the power supply wiring line CL3 in the area not overlapping the organic semiconductor layer 30. The power supply wiring line CL3 is provided in the same layer as the signal lines SL and is electrically coupled to the upper electrode 24 through a contact hole CH3 and a terminal 24a. The terminal 24a is provided in the same layer as the lower electrode 23.

With such a configuration, the upper electrode 24 of the photodiodes PD is coupled to the power supply circuit 123 included in the control circuit 122 via the terminal 24a and the power supply wiring line CL3. The power supply circuit 123 supplies a sensor power supply signal VDDSNS to the upper electrode 24 of the photodiodes PD.

The control circuit 122 (detection circuit 48 and power supply circuit 123) is disposed adjacent to the photodiodes PD in the second direction Dy in the peripheral area GA of the substrate 21. The control circuit 122 is a circuit that controls detection operations by supplying control signals to the photodiodes PD. Each of the photodiodes PD outputs, to the detection circuit 48, the electrical signal corresponding to the light emitted thereto as a detection signal Vdet. In the present embodiment, the detection signals Vdet of the photodiodes PD are sequentially output to the detection circuit 48 in a time-divisional manner. In other words, the signal lines SL are sequentially electrically coupled to the detection circuit 48 in a time-division manner. Thereby, the detection device 1 detects information on an object to be detected based on the detection signals Vdet from the photodiodes PD.

The control circuit 122 (detection circuit 48 and power supply circuit 123) is provided on the same substrate 21 as the photodiodes PD, but is not limited to this configuration. The control circuit 122 (detection circuit 48 and power supply circuit 123) may be provided on another control substrate coupled to the substrate 21, for example, through a flexible printed circuit board or the like. The detection circuit 48 and the power supply circuit 123 may each be formed as an individual circuit.

Although not illustrated in FIG. 1, the detection device 1 may include one or more light sources. For example, an inorganic light-emitting diode (LED) or an organic electroluminescent (EL) diode (organic light-emitting diode (OLED)) is used as the light source.

Light emitted from the light source is reflected by the object to be detected such as a finger and enters the photodiodes PD. As a result, the detection device 1 can detect a fingerprint by detecting a shape of asperities on the surface of the finger or the like. Alternatively, the light emitted from the light source may be reflected in the finger or the like, or transmitted through the finger or the like, and enter the photodiodes PD. As a result, the detection device 1 can detect information on a living body in the finger or the like. Examples of the information on the living body include, but are not limited to, pulse waves, pulsation, and a vascular image of the finger or a palm. That is, the detection device 1 may be configured as a fingerprint detection device to detect a fingerprint or a vein detection device to detect a vascular pattern of, for example, veins.

The following describes a multilayer configuration of the photodiode PD and the shield layer 26. FIG. 2 is a sectional view along II-II′ of FIG. 1.

In the following description, a direction from the substrate 21 toward a sealing film 28 in a direction orthogonal to a surface of the substrate 21 is referred to as “upper side” or simply “above”. A direction from the sealing film 28 toward the substrate 21 is referred to as “lower side” or simply “below”.

As illustrated in FIG. 2, the substrate 21 is an insulating substrate and is made using, for example, glass or a resin material. The substrate 21 is not limited to having a flat plate shape and may have a curved surface. In this case, the substrate 21 may be made of a film-like resin.

The signal line SL is provided on the substrate 21. The signal line SL is formed of, for example, metal wiring, and is formed of a material having better conductivity than the lower electrode 23 of the photodiode PD. A portion of the signal line SL (the right end side of the signal line SL in FIG. 2) is provided in a layer between the substrate 21 and the photodiode PD in the third direction Dz. The insulating film 27 is provided on the substrate 21 so as to cover the signal line SL. The insulating film 27 may be an inorganic insulating film or an organic insulating film. The insulating film 27 may be a single layer or a multilayered film.

The photodiode PD is provided on the insulating film 27. In more detail, the photodiode PD includes the lower electrode 23, the lower buffer layer 32, the active layer 31, the upper buffer layer 33, and the upper electrode 24. In the photodiode PD, the lower electrode 23, the lower buffer layer 32 (hole transport layer), the active layer 31, the upper buffer layer 33 (electron transport layer), and the upper electrode 24 are stacked in this order in the direction orthogonal to the substrate 21.

The lower electrode 23 is provided on the insulating film 27 and is electrically coupled to the signal line SL through the contact hole CH1 provided in the insulating film 27. The lower electrode 23 is an anode electrode of the photodiode PD and is formed, for example, of a light-transmitting conductive material such as indium tin oxide (ITO). The detection device 1 of the present embodiment is formed as a bottom-illuminated optical sensor in which the light from the object to be detected passes through the substrate 21 and enters the photodiode PD.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-type organic semiconductor and an n-type fullerene derivative (PCBM) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 (hole transport layer) is in direct contact with the top of the lower electrode 23, and is also provided in areas between the adjacent lower electrodes 23. The active layer 31 is in direct contact with the top of the lower buffer layer 32. The material of the hole transport layer is a metal oxide layer. For example, a tungsten oxide (WO3) or a molybdenum oxide is used as the metal oxide layer.

The upper buffer layer 33 (electron transport layer) is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, but may be formed as a multilayered film that includes an electron block layer and a hole block layer.

The upper electrode 24 is provided on the upper buffer layer 33. The upper electrode 24 is a cathode electrode of the photodiode PD and is continuously formed over the entire detection area AA. In other words, the upper electrode 24 is continuously provided on the photodiodes PD. The upper electrode 24 faces the lower electrodes 23 with the lower buffer layer 32, the active layer 31, and the upper buffer layer 33 interposed therebetween. The upper electrode 24 is formed, for example, of a light-transmitting conductive material such as ITO or indium zinc oxide (IZO).

The sealing film 28 is provided on the upper electrode 24. An inorganic insulating film, such as a silicon nitride film or an aluminum oxide film, or a resin film, such as an acrylic film, is used as the sealing film 28. The sealing film 28 is not limited to a single layer, but may be a multilayered film having two or more layers obtained by combining the inorganic film with the resin film mentioned above. The sealing film 28 well seals the photodiode PD, and thus can reduce water entering the photodiode PD from the upper surface side thereof.

The shield layer 26 is provided in the same layer as the lower electrode 23 on the insulating film 27. The shield layer 26 is formed of the same material as the lower electrode 23, for example, a light-transmitting conductive material such as ITO. However, the shield layer 26 is not limited to this material, but may be formed of a material different from that of the lower electrode 23, for example, a metal material.

The shield layer 26 is disposed with a gap interposed between itself and the lower electrode 23 in the first direction Dx. The shield layer 26 faces the signal line SL with the insulating film 27 interposed therebetween in the third direction Dz. A portion of the shield layer 26 is disposed between the signal line SL and the lower buffer layer 32 of the photodiode PD in the third direction Dz. In other words, the organic semiconductor layer 30 (lower buffer layer 32, active layer 31, and upper buffer layer 33) is provided so as to cover the lower electrode 23 and the portion of the shield layer 26. In the present embodiment, the lower buffer layer 32 is in direct contact with the lower electrode 23 and also with the portion of the shield layer 26.

The shield layer 26 extends outwardly with respect to a side surface of the organic semiconductor layer 30. That is, the shield layer 26 includes a portion thereof that overlaps the organic semiconductor layer 30 and a portion thereof that does not overlap the organic semiconductor layer 30. The portion of the shield layer 26 that overlaps the organic semiconductor layer 30, faces the upper electrode 24 with the organic semiconductor layer 30 interposed therebetween in the third direction Dz. The portion of the shield layer 26 that does not overlap the organic semiconductor layer 30 is covered with the sealing film 28.

As described above, the shield layers 26 are supplied with the reference voltage VCOM. As a result, the shield layer 26 reduces parasitic capacitance between the upper electrode 24 of the photodiode PD and the signal line SL, and reduces unintended capacitive coupling between the photodiode PD (upper electrode 24) and the signal line SL.

In more detail, as illustrated in FIG. 2, a diode Dp and capacitance Cp are generated between the lower electrode 23 and the upper electrode 24 that face each other with the organic semiconductor layer 30 interposed therebetween. The diode Dp and the capacitance Cp are a diode and capacitance that virtually serve as an optical sensor of the photodiode PD.

On the other hand, a diode Dw and capacitance Cw2 are generated between the shield layer 26 and the upper electrode 24 that face each other with the organic semiconductor layer 30 interposed therebetween.

Capacitance Cw1 is generated between the shield layer 26 and the signal line SL that face each other with the insulating film 27 interposed therebetween. The diode Dw and the capacitance Cw1 and Cw2 are parasitic diodes and parasitic capacitance generated in an electrode or wiring different from the lower electrode 23 that is a sensor electrode of the photodiode PD.

The shield layers 26 are supplied with the reference voltage VCOM having the same potential as the sensor reference voltage COM supplied to the lower electrodes 23. As a result, the capacitance Cw1 generated between the shield layer 26 and the signal line SL is reduced, and the capacitive coupling between the shield layer 26 and the signal line SL is reduced. Therefore, even if a leakage occurs from the parasitic diode (diode Dw), the shield layer 26 blocks the leakage, and the variation in the potential of the signal line SL that would be caused by the leakage from the diode Dw and the capacitance Cw2 is reduced.

As described above, the shield layer 26 reduces the unintended capacitive coupling between the photodiode PD (upper electrode 24) and the signal line SL, and the signal line SL is supplied with an electric charge from the diode Dp and the capacitance Cp that virtually serve as the optical sensor of the photodiode PD. Therefore, the detection device 1 of the present embodiment can improve the accuracy of detection.

As illustrated in FIG. 1, the width in the second direction Dy of the shield layer 26 is larger than the width in the second direction Dy of the signal line SL.

This configuration can reduce the capacitive coupling between the photodiode PD and the signal line SL on an end side of the shield layer 26 in the second direction Dy. Furthermore, as illustrated in FIGS. 1 and 2, the shield layer 26 extends outwardly with respect to a side surface of the organic semiconductor layer 30 in the first direction Dx. This configuration can reduce the capacitive coupling between a side surface of the photodiode PD and the signal line SL on an end side of the shield layer 26 in the first direction Dx.

The reference voltage VCOM supplied to the shield layers 26 is not limited to the voltage equal to the sensor reference voltage COM supplied to the lower electrode 23. The reference voltage VCOM only needs to be the predetermined fixed voltage signal and may be, for example, a voltage signal equal to the sensor power supply signal VDDSNS (sensor voltage) supplied to the upper electrode 24.

### First Modification of First Embodiment

FIG. 3 is a sectional view illustrating a detection device according to a first modification of the first embodiment. In the following description, the same components as those described in the embodiment above are denoted by the same reference numerals, and the description thereof will not be repeated.

As illustrated in FIG. 3, in a detection device 1A according to the first modification, a shield layer 26A is provided in a layer different from that of the lower electrode 23. More specifically, a first insulating film 27a and a second insulating film 27b are stacked on the substrate 21 so as to cover the signal line SL. The first insulating film 27a and the second insulating film 27b are stacked in this order on the substrate 21.

The shield layer 26A is provided between the first insulating film 27a and the second insulating film 27b in the third direction Dz. That is, the shield layer 26A is provided on the first insulating film 27a and is arranged so as to face the signal line SL with the first insulating film 27a interposed therebetween. The second insulating film 27b is provided on the first insulating film 27a so as to cover the shield layer 26A.

The lower electrode 23 is provided on the second insulating film 27b and is electrically coupled to the signal line SL through the contact hole CH1 that penetrates the first insulating film 27a and the second insulating film 27b in the thickness direction of these films. The organic semiconductor layer 30 (lower buffer layer 32, active layer 31, and upper buffer layer 33) of the photodiode PD is provided over an area that covers the lower electrode 23 and overlaps a portion of the shield layer 26A.

In also the first modification, the portion of the shield layer 26A is disposed between the signal line SL and the lower buffer layer 32 of the photodiode PD in the third direction Dz. In more detail, the shield layer 26A faces the lower buffer layer 32 with the second insulating film 27b interposed therebetween in the third direction Dz. An outer edge of the shield layer 26A is disposed so as to overlap an outer edge of the lower electrode 23.

Therefore, no gap is provided between the shield layer 26A and the lower electrode 23 in plan view, so that the capacitive coupling between the photodiode PD and the signal line SL is effectively reduced by the shield layer 26A.

As described above, in the first modification, the shield layer 26A is provided in a layer different from that of the lower electrode 23, and the shield layer 26A is less restricted by the shape and position of the lower electrode 23. Therefore, in the first modification, the flexibility of the design of the shield layer 26A, such as the shape and position thereof, can be higher than in the first embodiment.

The configuration of the shield layer 26A is not limited to the configuration in which an outer edge of the shield layer 26A is disposed so as to overlap an outer edge of the lower electrode 23. The shield layer 26A may be disposed such that a gap is formed between the shield layer 26A and the lower electrode 23 in plan view.

### Second Embodiment

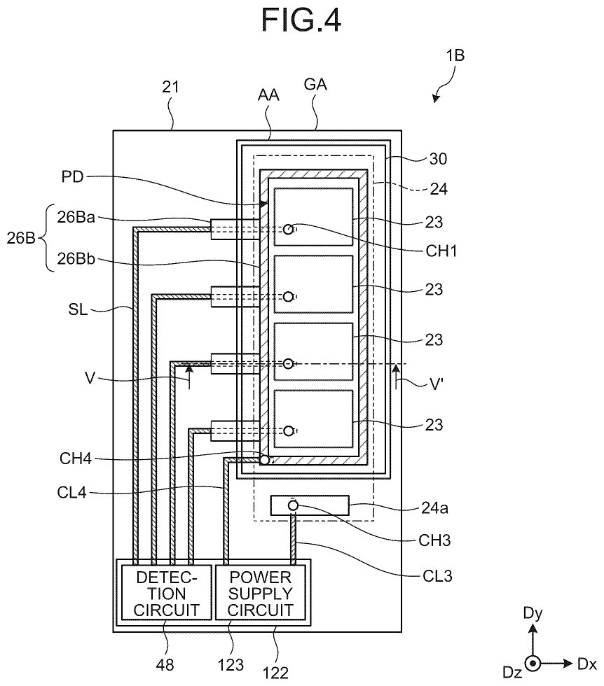

FIG. 4 is a plan view illustrating a detection device according to a second embodiment. As illustrated in FIG. 4, in a detection device 1B according to the second embodiment, a shield layer 26B includes a plurality of first shields 26Ba and a second shield 26Bb that surrounds the lower electrodes 23 in plan view. In FIG. 4, to facilitate viewing of the drawing, the second shield 26Bb is illustrated with diagonal lines.

Each of the first shields 26Ba is provided so as to overlap the signal line SL in plan view. A portion of the first shield 26Ba is disposed between the signal line SL and the lower buffer layer 32 of the photodiode PD in the third direction Dz. The detailed configuration of the first shield 26Ba is the same as that of the shield layer 26 of the first embodiment described above and will not be described again.

The frame-shaped second shield 26Bb surrounds the lower electrodes 23. For example, the second shield 26Bb has a quadrilateral shape having four sides. Ends of the first shields 26Ba in the first direction Dx are coupled to one side of the second shield 26Bb that extends in the second direction Dy. The second shield 26Bb is coupled, at a corner thereof, to power supply wiring line CL4 through a contact hole CH4. The power supply wiring line CL4 is electrically coupled to the power supply circuit 123.

With such a configuration, the power supply circuit 123 supplies the reference voltage VCOM to the first shields 26Ba and the second shield 26Bb of the shield layer 26B. The reference voltage VCOM is, for example, a voltage signal having an equal potential to the sensor reference voltage COM supplied to the lower electrodes 23.

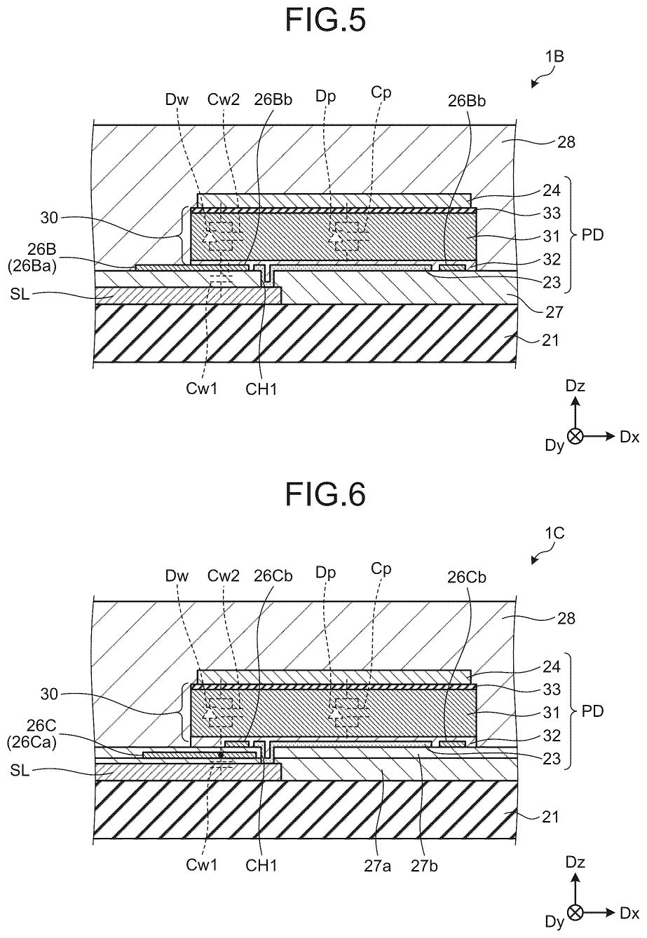

FIG. 5 is a sectional view along V-V′ of FIG. 4. As illustrated in FIG. 5, the first shields 26Ba and the second shield 26Bb of the shield layer 26B are provided in the same layer as the lower electrode 23 on the insulating film 27.

The organic semiconductor layer 30 (lower buffer layer 32, active layer 31, and upper buffer layer 33) of the photodiode PD is provided so as to cover the lower electrode 23 and cover a portion of the first shield 26Ba and the second shield 26Bb.

The first shield 26Ba has the same configuration as the shield layer 26 of the first embodiment described above, and the first shield 26Ba reduces the capacitive coupling between the photodiode PD (upper electrode 24) and the signal line SL. Furthermore, since the second shield 26Bb is provided so as to surround the lower electrodes 23, the second shield 26Bb can reduce unintended capacitive coupling between the lower electrodes 23 and wiring, electrodes, and the like in the peripheral area GA.

In more detail, as illustrated in FIGS. 4 and 5, in the detection area AA where the lower electrodes 23 are arranged, the photodiodes PD include the lower electrodes 23, the lower buffer layer 32, the active layer 31, the upper buffer layer 33, and the upper electrode 24 stacked in this order. As illustrated in FIG. 4, the second shield 26Bb is routed along the outermost periphery of the lower electrodes 23 and surrounds the lower electrodes 23 in a quadrilateral shape. Thus, the second shield 26Bb surrounds the entire outermost periphery of the lower electrodes 23. The second shield 26Bb is supplied with the reference voltage VCOM.

The upper electrode 24 extends in the second direction Dy from the detection area AA to the peripheral area GA. That is, the upper electrode 24 is provided on the organic semiconductor layer 30 in the detection area AA, covers a side surface of the organic semiconductor layer 30, and is coupled to the terminal 24a in the peripheral area GA. The upper electrode 24 is electrically coupled to the power supply wiring line CL3 routed in the peripheral area GA outside the second shield 26Bb. One side of the second shield 26Bb is disposed between the upper electrode 24 and one of the lower electrodes 23. The upper electrode 24 is provided so as to cover the side surface of the organic semiconductor layer 30 outside the detection area AA, and the one of the lower electrodes 23 is provided at the outermost periphery (position closest to the terminal 24a in the second direction Dy).

With this configuration, a leak current flows between the upper electrode 24 and the second shield 26Bb, and a leak current between the upper electrode 24 on the side surface of the organic semiconductor layer 30 and the lower electrode 23 at the outermost periphery is reduced.

The configuration of the shield layer 26B illustrated in FIGS. 4 and 5 is merely exemplary and can be changed as appropriate. For example, the second shield 26Bb is not limited to the frame shape. One or two of the four sides surrounding the lower electrodes 23 in the quadrilateral shape need not be provided.

### Second Modification of Second Embodiment

FIG. 6 is a sectional view illustrating a detection device according to a second modification of the second embodiment. As illustrated in FIG. 6, in a detection device 1C according to the second modification, a first shield 26Ca of a shield layer 26C is provided in a layer different from that of the lower electrode 23, and a second shield 26Cb is provided in the same layer as the lower electrode 23.

The first shield 26Ca of the shield layer 26C is provided between the first insulating film 27a and the second insulating film 27b in the third direction Dz. The second shield 26Cb is provided in the same layer as the lower electrode 23 on the second insulating film 27b. The second shield 26Cb is provided so as to overlap a portion of the first shield 26Ca.

The organic semiconductor layer 30 (lower buffer layer 32, active layer 31, and upper buffer layer 33) of the photodiode PD is provided over an area that covers the lower electrode 23 and the second shield 26Cb and overlaps a portion of the first shield 26Ca.

A plurality of the first shields 26Ca and the second shields 26Cb may be electrically coupled to each other through contact holes provided at any locations, or the first shields 26Ca and the second shields 26Cb may be electrically coupled to the power supply circuit 123 via different power supply wiring lines.

In also the second modification, in the same way as in the second embodiment described above, the first shield 26Ca reduces the capacitive coupling between the photodiode PD and the signal line SL. Furthermore, the second shield 26Cb can reduce the unintended capacitive coupling between the lower electrodes 23 and wiring, electrodes, and the like in the peripheral area GA.

In the first embodiment, the second embodiment, and the modifications thereof described above, the lower electrode 23 is the anode electrode of the photodiode PD, and the upper electrode 24 is the cathode electrode of the photodiode PD. However, the present disclosure is not limited to this configuration. The lower electrode 23 may be the cathode electrode of the photodiode PD, and the upper electrode 24 may be the anode electrode of the photodiode PD. In that case, in the photodiode PD, the lower buffer layer 32 is configured with an electron transport layer, and the upper buffer layer 33 is configured with a hole transport layer.

In the first embodiment, the second embodiment, and the modifications thereof described above, the configuration has been described in which the detection devices 1, 1A, 1B, and 1C each include four photodiodes PD. The present disclosure is not limited to this configuration. The detection devices 1, 1A, 1B, and 1C may each include five or more photodiodes PD. Alternatively, the detection devices 1, 1A, 1B, and 1C are not limited to a configuration including a plurality of photodiodes PD, but may each have at least one photodiode PD.

In the first embodiment, the second embodiment, and the modifications thereof described above, the example has been described in which the photodiodes PD are arranged in the second direction Dy in the detection area AA. However, the present disclosure is not limited to this example. The photodiodes PD may be arranged in the first direction Dx in the detection area AA, or may be arranged in the first direction Dx and the second direction Dy in the detection area AA to form a matrix having a row-column configuration. The lower electrodes 23 all have a quadrilateral outer shape, but the outer shape is not limited thereto. The lower electrode 23 can have other shapes, such as a polygonal shape and a circular shape.

While the preferred embodiments of the present disclosure have been described above, the present disclosure is not limited to the embodiments described above. The content disclosed in the embodiments is merely an example and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications thereof described above.

What is claimed is:

1. A detection device comprising:
a substrate;
a photodiode that is provided on the substrate and in which a lower electrode, a lower buffer layer, an active layer, an upper buffer layer, and an upper electrode are stacked on the substrate in the order as listed;
a signal line that is provided between the substrate and the photodiode in a direction orthogonal to the substrate and is electrically coupled to the lower electrode of the photodiode;
a detection circuit electrically coupled to the photodiode via the signal line; and
a shield layer that is provided between the signal line and the lower buffer layer in the direction orthogonal to the substrate and is configured to be supplied with a reference voltage.

2. The detection device according to claim 1, wherein
the lower buffer layer comprises one of a hole transport layer and an electron transport layer, and
the upper buffer layer comprises the other of the hole transport layer and the electron transport layer.

3. The detection device according to claim 1, wherein
the shield layer is provided in the same layer as the lower electrode, and
the lower buffer layer, the active layer, and the upper buffer layer are provided so as to cover the lower electrode and cover a portion of the shield layer.

4. The detection device according to claim 1, comprising a first insulating film and a second insulating film that are stacked on the substrate so as to cover the signal line, wherein
the shield layer is provided between the first insulating film and the second insulating film in the direction orthogonal to the substrate.

5. The detection device according to claim 1, wherein the reference voltage supplied to the shield layer is equal to a sensor voltage supplied to the upper electrode.

6. The detection device according to claim 1, wherein the reference voltage supplied to the shield layer is equal to a sensor reference voltage supplied to the lower electrode.

7. The detection device according to claim 1, wherein
the shield layer comprises a first shield and a second shield,
the first shield is disposed between the signal line and the lower buffer layer in the direction orthogonal to the substrate, and the second shield surrounds the lower electrode in plan view, and
the lower buffer layer, the active layer, and the upper buffer layer are provided so as to cover the lower electrode and cover a portion of the first shield and the second shield.

8. The detection device according to claim 1, comprising a plurality of the photodiodes, wherein
the signal line and the shield layer are provided for each of the photodiodes, and
the shield layers for the photodiodes are coupled to a common power supply wiring line.
